(19) United States
(12) Patent Application Publication
(10) Pub. No.: US 2020/0294887 A1
(43) Pub. Date: Sep. 17, 2020

(54) SEMICONDUCTOR DEVICE

(71) Applicant: Mitsubishi Electric Corporation, Chiyoda-ku, Tokyo (JP)

(72) Inventors: Masaki SATO, Tokyo (JP); Yuji SHIRAKATA, Tokyo (JP); Norihiro SUZUKI, Tokyo (JP); Shinji MURATA, Tokyo (JP)

(73) Assignee: Mitsubishi Electric Corporation, Chiyoda-ku, Tokyo (JP)

(21) Appl. No.: 16/758,960

(22) PCT Filed: Nov. 27, 2018
(86) PCT No.: PCT/JP2018/043527

§ 371 Date: Apr. 24, 2020

(30) Foreign Application Priority Data
Dec. 7, 2017 (JP) 2017-234991

(51) Int. Cl. H01L 23/467; H05K 7/20; H01L 23/367

(52) U.S. Cl. CPC H01L 23/467; H01L 23/367; H05K 7/20918; H05K 7/20163

(57) ABSTRACT

The semiconductor device includes a heat sink including fins and a base portion, and provided with a semiconductor module on a first surface and the fins on a second surface of the base portion; a housing attached to the base portion and covering the first surface of the base portion, the semiconductor module, electronic component, and a circuit board; a fan configured to cool the fins; and a first ventilation port and a second ventilation port each communicating inside and outside of the housing. The first ventilation port is provided above the half-height of the highest part in height of the electronic component from the circuit board. The second ventilation port extends through the first surface in the housing and the second surface of the base portion. The first ventilation port and the second ventilation port form a wind path in the housing.

### TECHNICAL FIELD

The present invention relates to a semiconductor device, and more particularly to a technique for cooling a heat-generating component covered with a housing.

### BACKGROUND ART

The heat radiation of the power semiconductor device, which is a heat-generating component, is designed with a heat sink, a fan, and the like. For example, a power semiconductor device has a configuration in which a heat sink including a base portion and the fins is screwed to one surface of a power semiconductor element. The heat generated by the power semiconductor element is radiated by cooling air generated by the fan or the like passing through the fins of the heat sink. However, the cooling effect of the component not attached to the heat sink is smaller than the cooling effect of the power semiconductor element attached to the heat sink. Further, there has been a problem that these components receive heat generated in the power semiconductor element and are overheated.

Patent Document 1 discloses an electronic apparatus in which a through hole extending through a base portion on which a heat-generating component is mounted is provided. The through hole eliminates air stagnation due to components that block ventilation, and improves the cooling effect.

### PRIOR ART DOCUMENTS

### Patent Documents

[Patent Document 1] Japanese Patent Application Laid-Open No. 2014-165409

### SUMMARY

### Problem to be Solved by the Invention

In the electronic apparatus described in Patent Document 1, a wind path in which cooling air flows is not formed and heat-generating components other than the heat-generating component attached to the base portion is not cooled.

The present invention has been made to solve the above-described problem, and an object to provide a semiconductor device in which a wind path in a housing is formed, and capable of cooling not only a semiconductor module mounted on a heat sink but also an electronic component provided in the housing.

### Means to Solve the Problem

According to the present invention, a semiconductor device includes a heat sink, a housing, a fan, a first ventilation port and a second ventilation port. The heat sink includes fins forming a first wind path in which first cooling air flows from a first end toward a second end and a base portion having a plate shape. The heat sink is provided with a semiconductor module on a first surface of the base portion and the fins standing on a second surface of the base portion. The housing is attached to the base portion of the heat sink and covers the first surface of the base portion, the semiconductor module, an electronic component operating in association with the semiconductor module, and a circuit board to which the electronic component is mounted. The housing accommodates the semiconductor module in a space formed between the first surface and the housing. The fan is configured to send the first cooling air toward the first wind path to cool the fins. The first ventilation port communicates inside of the housing and outside of the housing and is configured to take second cooling air into the housing. The second ventilation port communicates inside of the housing and outside of the housing and is configured to discharge the second cooling air taken into the housing to the outside of the housing. The first ventilation port is provided above a half-height of a highest part in height of the electronic component from the circuit board, the electronic component being mounted on a surface of the circuit board in the housing. The second ventilation port extends through the first surface in the housing and the second surface of the base portion. The semiconductor device further comprises, in the housing, a second wind path in which the second cooling air is taken in from the first ventilation port and discharged from the second ventilation port to the outside of the housing due to a pressure difference between inside of the housing and outside of the housing formed at the second ventilation port due to a flow of the first cooling air.

### Effects of the Invention

According to the invention, a semiconductor device is provided in which a wind path is formed in a housing and not only a semiconductor module attached to a heat sink but also an electronic component provided in the housing are cooled.

These and other objects, features, aspects and advantages of the present invention will become more apparent from the following detailed description when taken in conjunction with the accompanying drawings.

### BRIEF DESCRIPTION OF DRAWINGS

FIG. 1 A perspective view illustrating a configuration of a semiconductor device according to Embodiment 1.

FIG. 2 A cross-sectional view illustrating the configuration of the semiconductor device according to Embodiment 1.

FIG. 3 A perspective view illustrating a configuration of a heat sink included in the semiconductor device according to Embodiment 1.

FIG. 4 A diagram illustrating a pressure distribution at the time of air blowing inside and outside the semiconductor device according to Embodiment 1.

FIG. 5 A diagram illustrating a flow distribution at the time of air blowing inside and outside the semiconductor device according to Embodiment 1.

FIG. 6 A diagram illustrating a temperature distribution at the time of air blowing inside and outside the semiconductor device according to Embodiment 1.

FIG. 7 A cross-sectional view illustrating a configuration of a semiconductor device according to Modification 1 of Embodiment 1.

FIG. 8 A cross-sectional view illustrating a configuration of a semiconductor device according to Modification 2 of Embodiment 1.

FIG. 9 A cross-sectional view illustrating a configuration of a semiconductor device according to Modification 3 of Embodiment 1.

FIG. 10 A perspective view illustrating a configuration of a semiconductor device according to Modification 4 Embodiment 1.

FIG. 11 A cross-sectional view illustrating the configuration of the semiconductor device according to Modification 4 of Embodiment 1.

FIG. 12 A perspective view illustrating a configuration of a semiconductor device according to Embodiment 2.

FIG. 13 A perspective view illustrating the configuration of the semiconductor device according to Embodiment 2.

FIG. 14 A cross-sectional view illustrating the configuration of the semiconductor device according to Embodiment 2.

FIG. 15 A perspective view illustrating a configuration of a heat sink included in the semiconductor device according to Embodiment 2.

FIG. 16 A cross-sectional view illustrating a configuration of a semiconductor device according to Embodiment 3.

FIG. 17 A cross-sectional view illustrating a configuration of a semiconductor device according to Embodiment 4.

### DESCRIPTION OF EMBODIMENTS

### Embodiment 1

(Configuration of Semiconductor Device)

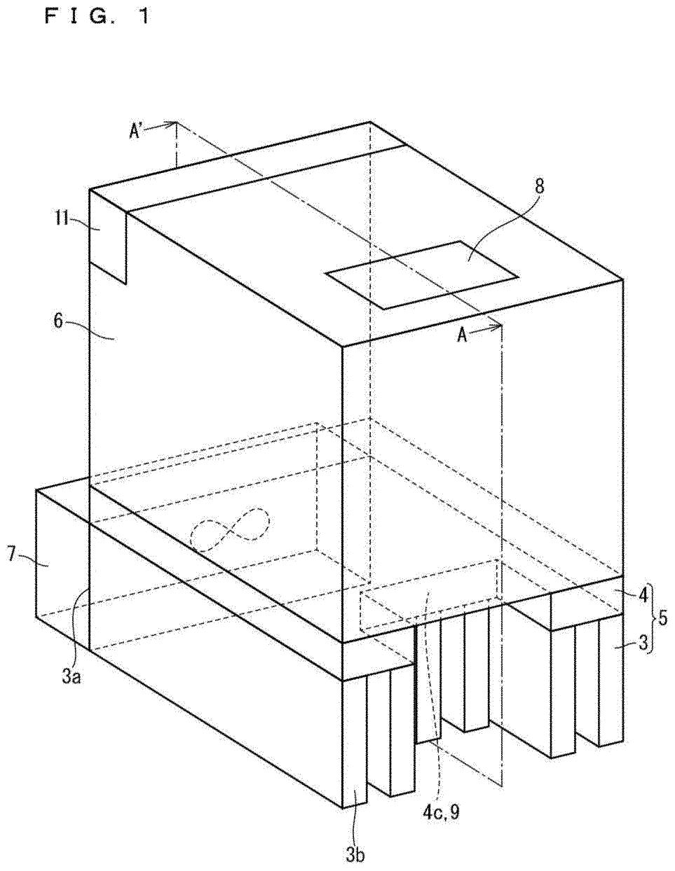

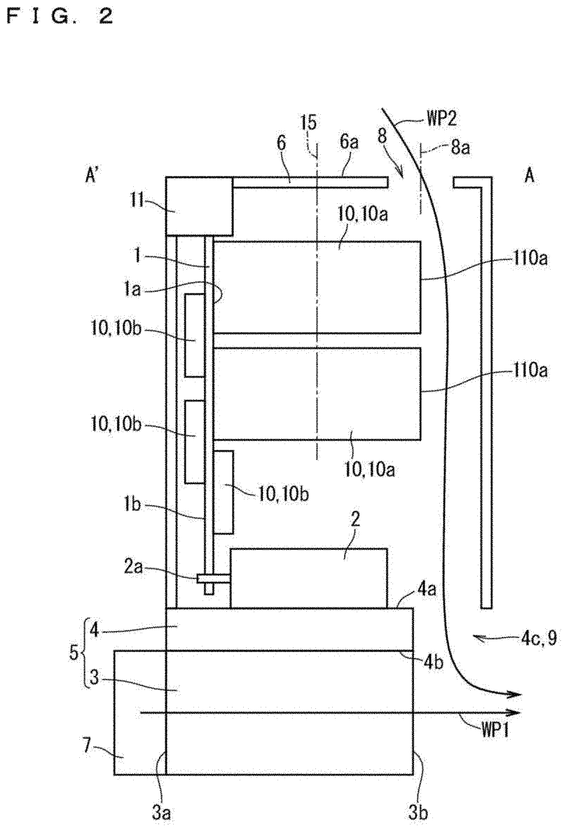

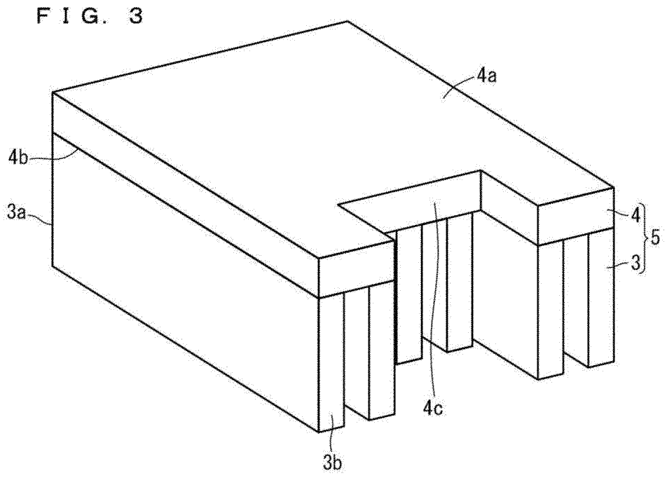

A semiconductor device according to Embodiment 1 will be described. FIG. 1 is a perspective view schematically illustrating a configuration of a semiconductor device according to Embodiment 1. FIG. 2 is a cross-sectional view schematically illustrating the configuration of the semiconductor device according to Embodiment 1, showing a cross section taken along line A-A′ illustrated in FIG. 1. FIG. 3 is a perspective view schematically illustrating a configuration of a heat sink 5 included in the semiconductor device according to Embodiment 1. In Embodiment 1, the mounting direction of the semiconductor device is such that one end 3a (the first end) of the heat sink 5 is on the lower side and the other end 3b (the second end) is on the upper side.

As illustrated in FIG. 2, the semiconductor device includes a heat sink 5 to which the semiconductor module 2 is attached, a housing 6, a fan 7, a first ventilation port 8, and a second ventilation port 9. The semiconductor device according to Embodiment 1 includes a circuit board 1 and electronic components 10 in addition to the above configuration. The semiconductor module 2 is, for example, a power semiconductor module. The power semiconductor module includes, for example, at least one semiconductor element (not shown). The semiconductor element is, for example, a power semiconductor element including a wide-band-gap semiconductor such as SiC or GaN. The semiconductor device is, for example, a power semiconductor device including a power semiconductor element.

The heat sink 5 includes fins 3 forming the first wind path WP1 in which the first cooling air flows from the one end 3a to the other end 3b, and a base portion 4 having a plate shape. The semiconductor module 2 is provided on one surface 4a (the first surface) of the base portion 4, and the fins 3 are provided standing on the other surface 4b (the second surface). As illustrated in FIG. 3, in Embodiment 1, a plurality of fins 3 are provided, and each fin 3 is provided in parallel with each other. Further, the base portion 4 is provided with a cutout portion 4c extending through the one surface 4a and the other surface 4b. The cutout portion 4c is provided on at least a part of one side forming the plate shape of the base portion 4. The one side where the cutout portion 4c is provided is located on the other end 3b side of the fins 3. The cutout portion 4c extends through the base portion 4 and the fins 3. However, the form of the cutout portion 4c is not limited thereto. The cutout portion may have a structure extending through the base portion 4 and may have a structure not extending through the fins 3. Although the cutout portion 4c has a rectangular shape in plan view, the shape is not limited to a rectangle and may be any shape.

The housing 6 is attached to the base portion 4 of the heat sink 5 and covers the one surface 4a of the base portion 4, the semiconductor module 2, the electronic components 10, and the circuit board 1. The housing 6 accommodates the semiconductor module 2 in a space formed between the one surface 4a of the base portion 4 and the housing 6. The electronic components 10 are electronic components that operate in association with the semiconductor module. The electronic components 10 are mounted on a surface 1a of the circuit board 1. Also, in Embodiment 1, the electronic components 10 are also provided on the back surface 1b of the circuit board 1. Further, the circuit board 1 mounts the semiconductor module 2 provided in the housing 6.

The fan 7 sends the first cooling air to the fins 3, that is, the first wind path WP1, and cools the fins 3. In Embodiment 1, the fan 7 is provided on the one end 3a side of fins 3. That is, the fan 7 is provided on the side opposite to the cutout portion 4c. The fan 7 sends the first cooling air by sending out air from the one end 3a side toward the other end 3b side. Thereby, the fan 7 forcibly air-cools the heat sink 5.

The first ventilation port 8 communicates the inside of the housing 6 and the outside of the housing 6 and takes in the second cooling air into the housing 6. The first ventilation port 8 is provided above the half-height of the highest part in height of the electronic components 10 from the surface 1a of the circuit board 1. Here, of the electronic components 10, the height of the capacitor 10a described later from the circuit board 1 is the highest. Therefore, the first ventilation port 8 is provided above the half-height 15 of the uppermost part 110a of the capacitors 10a. In the semiconductor device illustrated in FIG. 2, the direction in which the other end 3b of the fins 3 is located (i.e. the right side in the drawing) is upward. The first ventilation port 8 is provided such that the center 8a of the first ventilation port 8 is located above the half-height 15 and the whole thereof is located above the half-height 15. In Embodiment 1, the first ventilation port 8 is provided in the housing 6. Here, the first ventilation port 8 is provided on the upper surface 6a of the housing 6 on the other end 3b side of the fins 3, that is, above the cutout portion 4c of the base portion 4. And, although the first ventilation port 8 has a rectangular shape in FIG. 1, the shape is not limited to a rectangle and may be any shape. Further, the first ventilation port 8 may be a hole or a mesh formed of a plurality of holes.

The second ventilation port 9 extends through the one surface 4a in the housing 6 and the other surface 4b of the base portion 4. In Embodiment 1, the second ventilation port 9 is formed by the cutout portion 4c of the base portion 4. The second ventilation port 9 may be configured to include at least a part of the cutout portion 4c of the base portion 4. For example, as illustrated in FIG. 2, the second ventilation port 9 is preferably provided above the half-height 15 of the uppermost parts 110a of the capacitors 10a that are the tallest electronic components 10. The second ventilation port 9 communicates the inside of the housing 6 and the outside of the housing 6 and discharges the second cooling air which has been taken in the housing 6 to the outside of the housing 6.

Due to the pressure difference between the inside of the housing 6 and the outside of the housing 6 formed at the second ventilation port 9 due to the flow of the first cooling air, the first ventilation port 8 and the second ventilation port 9 form the second wind path WP2 in which the second cooling air is taken in from the first ventilation port 8 and discharged from the second ventilation port 9 to the outside of the housing 6. In Embodiment 1, the cross-sectional area of the first ventilation port 8 and the cross-sectional area of the second ventilation port 9 are substantially the same.

The electronic components 10 are provided in the housing 6 along the second wind path WP2. The electronic component 10 includes an electric/electronic component, and is, for example, a capacitor 10a. Alternatively, the electronic component 10 includes, for example, another semiconductor module 10b. The capacitor 10a is, for example, a large-sized capacitor 10a larger than the semiconductor module 2 or another semiconductor module 10b. The electronic component 10 is not limited to the capacitor 10a, and may include, for example, a transformer or a coil. The housing 6 also covers the circuit board 1 and the electronic components 10 and is attached to the base portion 4 of the heat sink 5. Further, the housing 6 may be provided with an external connection terminal 11. The external connection terminal 11 is connected to the semiconductor module 2 and the electronic components 10 via the circuit board 1.

(Cooling Operation of Semiconductor Device)

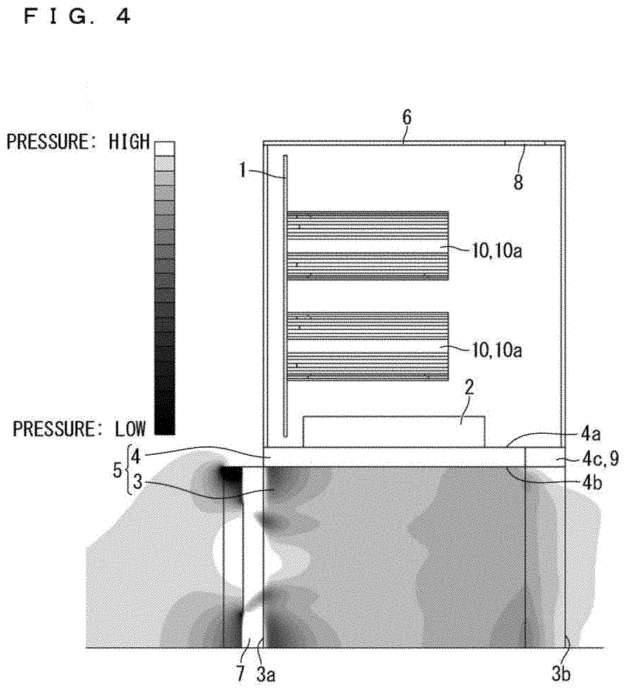

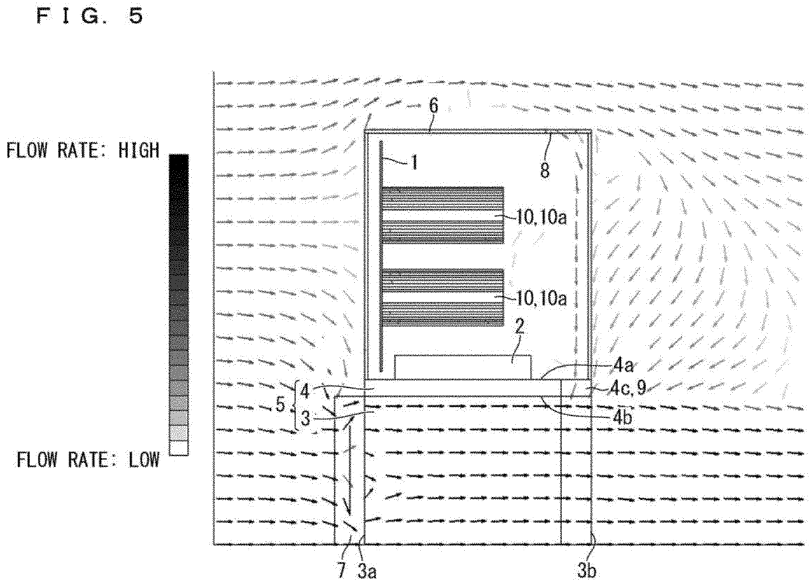

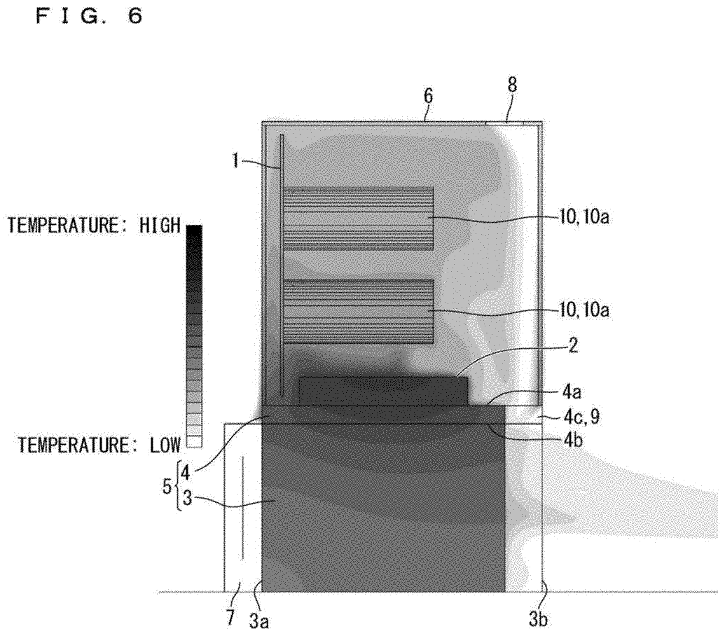

Next, the operation of the semiconductor device will be described. FIG. 4 is a diagram illustrating a pressure distribution at the time of air blowing inside and outside the semiconductor device according to Embodiment 1. FIG. 5 is a diagram illustrating a flow distribution at the time of air blowing inside and outside the semiconductor device according to Embodiment 1. FIG. 6 is a diagram illustrating a temperature distribution at the time of air blowing inside and outside the semiconductor device according to Embodiment 1. FIGS. 4 to 6 illustrate the analysis results by the finite element method.

The analysis model is as follows. The size of the housing 6 is 90 mm in depth×150 mm in width×150 mm in height. In FIG. 4, the direction perpendicular to the sheet surface is the depth direction, the horizontal direction is the width direction, and the vertical direction is the height direction. The size of the heat sink 5 is 90 mm in depth×150 mm in width×100 mm in height. The size of the first ventilation port 8 is 50 mm in depth×20 mm in width. The size of the cutout portion 4c, that is, the second ventilation port 9, is 50 mm in depth×20 mm in width. The calorific value of the semiconductor module is 20 W. Note that the other components do not generate heat. The fan 7 sends the first cooling air having a wind speed of 5 m/s. Note that a wind speed is not set around the housing 6. The outside air temperature of the housing 6 is 20° C.

When the fan 7 is driven, the first cooling air flows from the one end 3a of the fins 3 toward the other end 3b. As illustrated in FIG. 4, the first cooling air flows, thereby the pressure outside the housing 6 at the second ventilation port 9, that is, at the cutout portion 4c of the base portion 4 decreasing in Embodiment 1. The air in the housing 6 is enclosed with the housing 6 and the base portion 4; therefore, the pressure in the housing 6 is higher than the pressure of the air flowing through the fins 3 immediately below the base portion 4. The gaseous body flows from a high-pressure portion to a low-pressure portion; therefore, as illustrated in FIG. 5, the high-pressure air in the housing 6 is discharged to the outside of the housing 6 where the pressure is low through the second ventilation port 9. When the air inside the housing 6 is discharged through the second ventilation port 9, the pressure inside the housing 6 tends to be lower; therefore, outside air flows into the housing 6 from outside the housing 6 through the first ventilation port 8. As a result, a wind path in which the second cooling air flows from the first ventilation port 8 to the second ventilation port 9 is formed. The wind path in which the second cooling air flows is the second wind path WP2 illustrated in FIG. 2, and the second wind path WP2 is formed so as to connect the first ventilation port 8 and the second ventilation port 9. Although not illustrated in FIG. 5 because the resolution is not sufficient enough, the wind speed of the second cooling air on the surface 1a of the circuit board 1 is lower than the wind speed of the second cooling air on the capacitors 10a. For example, the wind speed of the second cooling air at the surface 1a of the circuit board 1 is lower than the wind speed of the second cooling air at the uppermost parts 110a of the capacitors 10a, which are the electronic components 10 having the highest height from the surface 1a.

As illustrated in FIG. 6, by the second cooling air, the semiconductor device cools the electronic components 10 such as the semiconductor module 2 and the capacitors 10a arranged close to the second wind path WP2 in which the second cooling air flows. In particular, the upper part of the capacitors 10a is cooled. Further, the semiconductor device also cools the heat sink 5 by the first cooling air, and as a result, the semiconductor module 2 is cooled.

(Effects)

In summary, the semiconductor device according to Embodiment 1 includes the heat sink 5, the housing 6, the fan 7, the first ventilation port 8 and the second ventilation port 9. The heat sink 5 includes the fins 3 forming the first wind path WP1 in which the first cooling air flows from the one end 3a (the first end) toward the other end 3b (the second end) and the base portion 4 having a plate shape. The heat sink 5 is provided with the semiconductor module 2 on one surface 4a (the first surface) and the fins 3 standing on the other surface 4b (the second surface) of the base portion 4. The housing 6 is attached to the base portion 4 of the heat sink 5 and covers the one surface 4a of the base portion 4, the semiconductor module 2, the electronic components 10 operating in association with the semiconductor module 2, and the circuit board 1 to which the electronic components 10 is mounted. The housing 6 accommodates the semiconductor module 2 in a space formed between the one surface 4a and housing 6. The fan 7 configured to send the first cooling air toward the first wind path WP1 to cool the fins 3. The first ventilation port 8 communicates inside of the housing 6 and outside of the housing 6 and is configured to take the second cooling air into the housing 6. The second ventilation port 9 communicates inside of the housing 6 and outside of the housing 6 and is configured to discharge the second cooling air taken into the housing 6 to the outside of the housing 6. The first ventilation port 8 is provided above a half-height of the highest part (uppermost parts 110a) in height of the electronic components 10 from the circuit board 1, the electronic components are mounted on a surface (surface 1a) of the circuit board 1 in the housing 6. The second ventilation port 9 extends through the one surface 4a in the housing 6 and the other surface 4b of the base portion 4. Due to the pressure difference between the inside of the housing 6 and the outside of the housing 6 formed at the second ventilation port 9 due to the flow of the first cooling air, the first ventilation port 8 and the second ventilation port 9 form, in the housing 6, the second wind path WP2 in which the second cooling air is taken in from the first ventilation port 8 and discharged from the second ventilation port 9 to the outside of the housing 6. A wind speed of the second cooling air on the surface (surface 1a) of the circuit board 1 is lower than a wind speed of the second cooling air on the electronic components 10.

With the above configuration, the semiconductor device can form the second wind path WP2 in which the second cooling air flows, between the first ventilation port 8 and the second ventilation port 9. The semiconductor device can flow the second cooling air in the housing 6 without deteriorating the performance of the heat sink 5. Accordingly, the air stagnation generated close to the semiconductor module 2 in the housing 6 can be eliminated, and the hot air accumulated around the semiconductor module 2 can be discharged. Further, the semiconductor device also cools the electronic components 10 mounted near the second wind path WP2. For example, even when large-sized electronic components 10 such as the capacitors 10a are mounted, the semiconductor device efficiently performs cooling. As a result, the lives of the capacitors 10a are extended, and moreover, the reliability of the semiconductor device is improved. The first ventilation port 8 is located above the half-height 15 of the uppermost parts 110a of the capacitors 10a that are the tallest electronic components among the electronic components 10 mounted on the surface 1a of the circuit board 1. Therefore, the semiconductor device can efficiently discharge high-temperature air in the housing 6 without increasing the wind speed close to the surface 1a of the circuit board 1. In addition, foreign substances such as dust are unlikely to adhere to the circuit board 1; therefore, taking measures against foreign substances such as coating on the surface 1a of the circuit board 1 is unnecessary. For example, when the wind speed close to the surface 1a of the circuit board 1 is 0.3 m/s, foreign substances such as dirt and dust are unlikely to adhere, so that the taking measures against foreign substance is unnecessary. Accordingly, by satisfying the relationship of “wind speed of the second wind path WP2”≥0.3 m/s≥“wind speed close to the surface 1a of the circuit board 1”, the downsizing, weight reduction, and cost reduction of the semiconductor device can be realized. The above-described wind speed is an example, and may be any wind speed at which the semiconductor device does not break down due to dirt or dust. The respective positions of the first ventilation port 8 and the second ventilation port 9 or the arrangement of the electronic components 10 illustrated in Embodiment 1 are an example, and are not limited to the above. The arrangement of the first ventilation port 8 and the second ventilation port 9 may be determined, for example, according to the arrangement of the electronic components 10 mounted on the circuit board 1. That is, the first ventilation port 8 and the second ventilation port 9 may be provided so that the second wind path WP2 is formed in accordance with the arrangement of the electronic components 10. Further, the semiconductor device according to Embodiment 1 encloses the circuit board 1, the semiconductor module 2, and the electronic components 10 with the housing 6 and the heat sink 5; therefore, noise transmitted from outside the housing 6 into the housing 6 is reduced.

Further, the second ventilation port 9 of the semiconductor device of Embodiment 1 is provided above the half-height 15 of the highest part (uppermost part 110a) in height from the circuit board 1.

Such a semiconductor device can cause the wind speed of the second cooling air on the surface 1a of the circuit board 1 to be lower than the wind speed of the second cooling air on the electronic components. Therefore, the semiconductor device can discharge high-temperature air in the housing 6 while reducing the adhesion of foreign substances onto the surface 1a of the circuit board 1.

Also, the first ventilation port 8 of Embodiment 1 is provided in the housing 6. The base portion 4 includes a cutout portion 4c extending through the one surface 4a and the other surface 4b on at least a part of one side forming the plate shape. The one side where the cutout portion 4c is provided is located on the other end 3b side of the fins 3. The second ventilation port 9 includes at least a part of the cutout portion 4c.

With such a configuration, without requiring additional cooling members such as the fan 7, the semiconductor device improves cooling performance for the inside of the housing 6 by only adding processing costs to form the first ventilation port 8 and the second ventilation port 9. And, when the first ventilation port 8 is a mesh, dust is prevented from entering into the housing 6. The cutout portion 4c needs to have a configuration in which the cutout portion 4c extends the inside of the housing 6 and the outside of the housing 6, and as long as the configuration is like the one in which the cutout portion 4c extends through the base portion 4 described above, the fins may not be required to be penetrated. In addition, the cutout portion 4c as the second ventilation port 9 may have any configuration as long as the second cooling air is allowed to flow in a direction perpendicular to the direction in which the first cooling air flows. Also, even when the cutout portion 4c that is the second ventilation port 9 is provided on the windward side of the first cooling wind, that is, on the one end 3a side of the fins 3, the cooling wind flows from the second ventilation port 9 into the housing 6. However, considering that the gas volume of the first cooling air flowing through the fins 3 is reduced and the cooling efficiency of the heat sink 5 is reduced, the cutout portion 4c is preferably provided on the other end 3b side of the fins 3.

In the semiconductor device of Embodiment 1, the fan 7 is provided on the one end 3a side of the fins 3, and sends out the first cooling air by sending air from the one end 3a side toward the other end 3b side.

With such a configuration, the semiconductor device can form the second wind path WP2 for the second cooling air in the housing 6 without reducing the gas volume of the first cooling air. That is, the electronic components 10 and the like in the housing 6 can be cooled without impairing the cooling effect of the heat sink 5.

Further, the semiconductor device of Embodiment 1 includes an electronic components 10 operating in association with semiconductor module 2 provided in the housing 6 along the second wind path WP2.

With such a configuration, the electronic components 10 are efficiently cooled by the second cooling air flowing through the second wind path WP2 formed depending on each position of the first ventilation port 8 and the second ventilation port 9.

Further, the semiconductor device according to Embodiment 1 exhibits a greater effect, when a power semiconductor module that controls a higher power is mounted as the semiconductor module 2 rather than a semiconductor module that controls a lower power is mounted as the semiconductor module 2. The calorific value of the power semiconductor module is higher than the calorific value of the semiconductor module that controls the low power. Therefore, the heat sink 5 is attached to the power semiconductor module to improve the heat radiation performance. On the other hand, as described above, the power semiconductor device including the power semiconductor module has a configuration covered with the housing 6 to prevent contact with the outside. The circuit board 1 and the electronic component 10 and the like that operates in association with the semiconductor module 2 are also provided in the housing 6. The housing 6 prevents the circulation of air in the housing 6; therefore, an independent heat radiation design for the electronic components 10 and the like that are not attached to the heat sink 5 is required. According to the configuration of the semiconductor device in Embodiment 1, the second wind path WP2 for the second cooling air is formed in the housing 6; therefore, even if the semiconductor device is a power semiconductor device, the circuit board 1 and the electronic components 10 in the housing 6 can be effectively cooled.

(Modification 1 of Embodiment 1)

In the semiconductor device illustrated in Embodiment 1, the second wind path WP2 for the second cooling air is formed above the large electronic components 10 such as another semiconductor module 10b and capacitor 10a mounted on the circuit board 1. Then, the second cooling air cools the components mounted on the circuit board 1. The configuration and operation of the semiconductor device are not limited thereto. In addition to the change of the second wind path WP2 for the second cooling air formed in the housing 6, the change of the electronic components 10 to be cooled are implemented by either changing the positions of the first ventilation port 8 and the second ventilation port 9 or changing the arrangement of the electronic components 10 to be mounted on the circuit board.

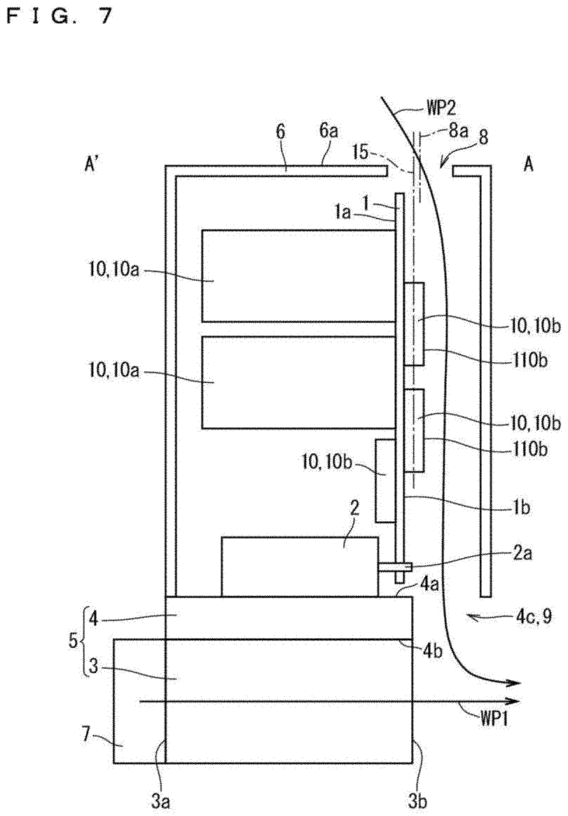

FIG. 7 is a cross-sectional view illustrating a configuration of a semiconductor device according to Modification 1 of Embodiment 1. Although the position of the first ventilation port 8 and the position of the second ventilation port 9 are the same as those of Embodiment 1, the arrangement of the circuit board 1 is different from that of Embodiment 1. The circuit board 1 of the semiconductor device according to Modification 1 of Embodiment 1 is attached at a position which is 180 degrees inverted with respect to the mounting position of the circuit board 1 of the semiconductor device illustrated in FIG. 2. The first ventilation port 8 is provided above the half-height of the highest part in height of the electronic components 10 from the back surface 1b of the circuit board 1. Here, the height of the other semiconductor module 10b from the circuit board 1 is the highest. Therefore, the first ventilation port 8 is provided above the half-height 15 of the uppermost parts 110b of the other semiconductor module 10b. In the semiconductor device illustrated in FIG. 7, the direction in which the other end 3b of the fins 3 is located (i.e. the right side in the drawing) is upward. Here, the first ventilation port 8 is provided such that the center 8a of the first ventilation port 8 is located above the half-height 15. Although not illustrated, as in Embodiment 1, the entire first ventilation port 8 may be provided so as to be positioned above the half-height 15 described above. The second wind path WP2 for the second cooling air defined by the first ventilation port 8 and the second ventilation port 9 is formed on the back surface 1b side of the circuit board 1. Here, the back surface 1b of the circuit board 1 is a surface opposite to the surface 1a on which the capacitors 10a are mounted.

With such a configuration, the semiconductor device can cool the circuit board 1 and the electronic components 10 and the like attached to the back surface 1b of the circuit board 1.

(Modification 2 of Embodiment 1)

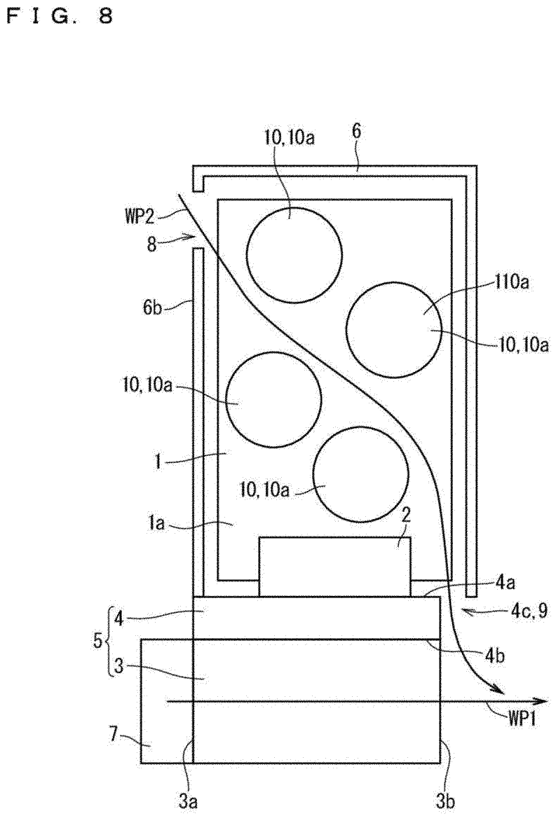

FIG. 8 is a cross-sectional view illustrating a configuration of a semiconductor device according to Modification 2 of Embodiment 1. The circuit board 1 of Modification 2 is attached at a position rotated by 90 degrees with respect to the attaching position of the circuit board 1 of the semiconductor device according to Embodiment 1 illustrated in FIG. 2. The first ventilation port 8 is provided on the side surface 6b of the housing 6. The side surface 6b is located on the one end 3a side of the fins 3. That is, the first ventilation port 8 and the second ventilation port 9 are provided at diagonal positions on the circuit board 1, respectively. The first ventilation port 8 is provided above the half-height of the highest part (uppermost parts 110a) in height of the electronic components 10 from the surface 1a of the circuit board 1. In the semiconductor device illustrated in FIG. 8, the front side in the drawing is the upper side. Further, the second ventilation port 9 is also preferably provided above the half-height of the uppermost part 110a. Also, large electronic components 10, such as a capacitor 10a mounted on the circuit board 1, are arranged in a manner that the second wind path WP2 for the second cooling air is not completely blocked. Further, the electronic components 10 that need to be cooled are arranged close to the second wind path WP2 for the second cooling air.

With such a configuration, the second wind path WP2 for the second cooling air is formed between the first ventilation port 8 and the second ventilation port 9 provided diagonally from each other. The semiconductor device can cool the electronic components 10 that need to be cooled by the second cooling air.

(Modification 3 of Embodiment 1)

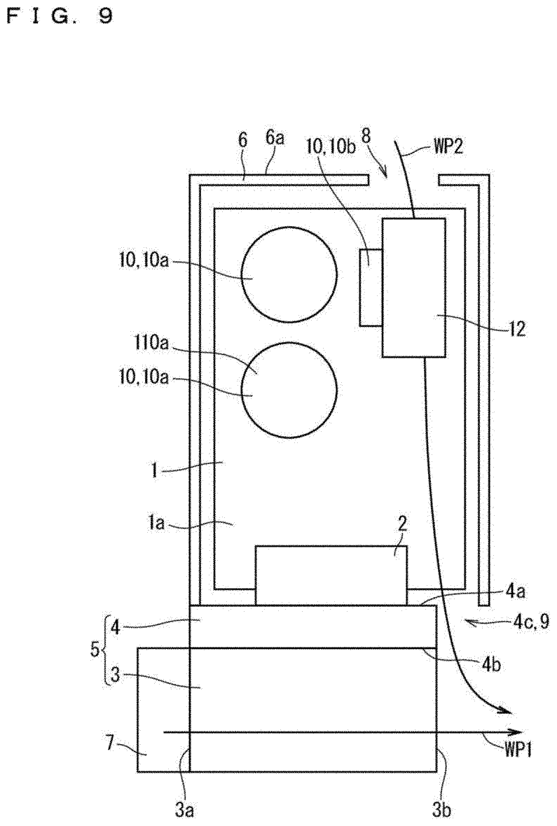

FIG. 9 is a cross-sectional view illustrating a configuration of a semiconductor device according to Modification 3 of Embodiment 1. The circuit board 1 of Modification 3 is attached at a position rotated by 90 degrees with respect to the attaching position of the circuit board 1 of the semiconductor device according to Embodiment 1 illustrated in FIG. 2. The position of the first ventilation port 8 and the position of the second ventilation port 9 are the same as those in Embodiment 1. Specifically, the first ventilation port 8 is provided above the half-height of the highest part (uppermost parts 110a) in height of the electronic components from the surface 1a of the circuit board 1. In the semiconductor device illustrated in FIG. 9, the front side in the drawing is the upper side. Further, the second ventilation port 9 is also preferably provided above the half-height of the uppermost part 110a. Electronic components 10 and an electronic component heat sink 12 for cooling the electronic component 10 are further provided in the housing 6. The mounting position of the electronic component 10 to which the electronic component heat sink 12 is attached is a position that overlaps the second wind path WP2 for the second cooling air flowing from the first ventilation port 8 to the second ventilation port 9. Here, the electronic component 10 is another semiconductor module 10b different from the semiconductor module 2 attached to the heat sink 5. The electronic component heat sink 12 is, for example, a heat sink smaller than the heat sink 5 to which the semiconductor module 2 is attached.

With such a configuration, the semiconductor device allows the electronic component heat sink 12 to be forcibly cooled, thereby cooling of the electronic component 10 (another semiconductor module 10b) is ensured. Therefore, a change in characteristics of the electronic component 10 due to a temperature change is reduced, and the reliability of the semiconductor device on which the electronic component 10 is mounted is improved. Further, the heat sink 5 to which the semiconductor module 2 is attached and the electronic component heat sink 12 are arranged separately. Therefore, the semiconductor device can simultaneously cool the semiconductor module 2 and the electronic component 10 each having different temperature rise rates.

(Modification 4 of Embodiment 1)

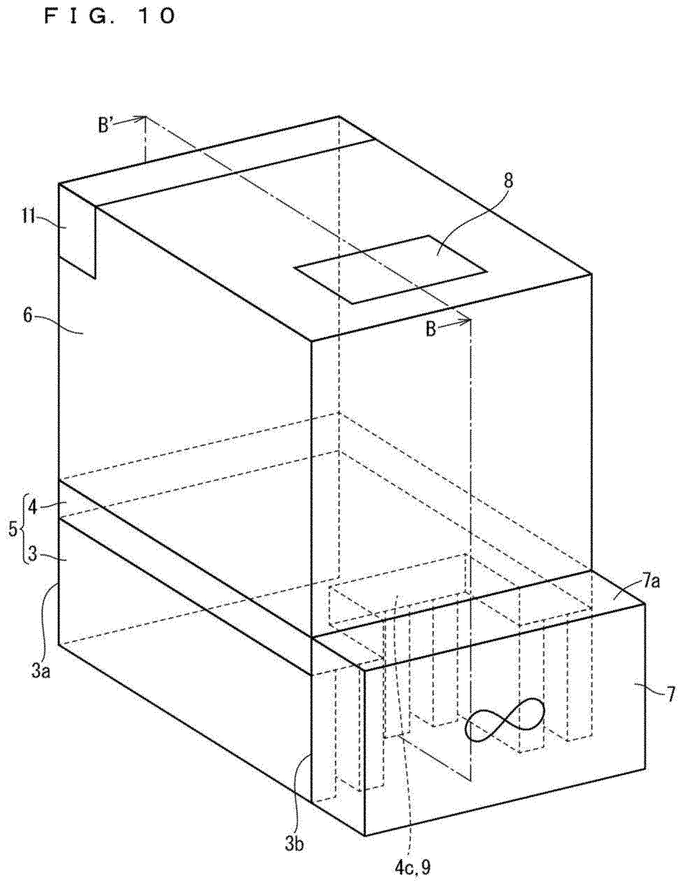

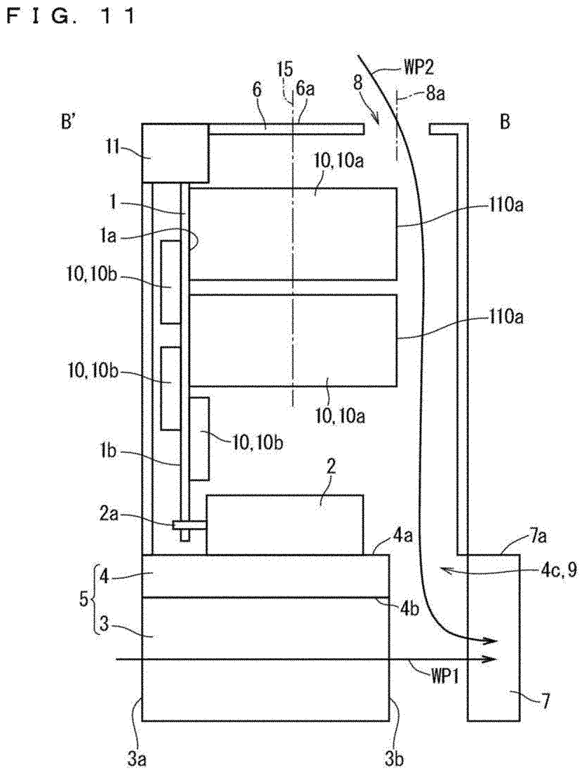

Although, the semiconductor device according to Embodiment 1 includes the fan 7 provided on the side opposite to the cutout portion 4c, that is, on the one end 3a side of the fins 3, the arrangement of the fan 7 is not limited thereto. FIG. 10 is a perspective view illustrating a configuration of a semiconductor device according to Modification 4 Embodiment 1. FIG. 11 is a cross-sectional view illustrating a configuration of a semiconductor device according to Modification 4 of Embodiment 1, showing a cross section taken along the line B-B′ illustrated in FIG. 10.

The fan 7 is provided on the cutout portion 4c side, that is, the other end 3b side of the fins 3. The fan 7 sends the first cooling air toward the other end 3b side by drawing in air from one end 3a side of the fins 3. Even with the semiconductor device having such a configuration, the same effects as those of the Embodiment 1 can be obtained.

Further, the upper end portion 7a of the fan 7 is preferably provided at a position higher than the position of the cutout portion 4c. That is, the fan 7 is preferably provided such that the upper end portion 7a is provided above a surface defined by the other surface 4b of the base portion 4. The upper side is a direction in which the upper surface 6a of the housing 6 is located. With such a configuration, the fan 7 also takes in the second cooling air discharged from the second ventilation port 9 and discharges the air to the outside of the housing 6.

(Modification 5 of Embodiment 1)

As the fan 7, a fan 7 of which ventilation speed, that is, the rotational speed is variable may be used. As the ventilation speed of the fan 7 increases, the pressure of the air flowing through the fins 3 decreases. As a result, the pressure difference between the inside of the housing 6 and the outside of the housing 6 increases. Accordingly, the amount of the second cooling air flowing between the first ventilation port 8 and the second ventilation port 9 increases as compared with the case where the ventilation speed of the fan 7 is low. Thus, the gas volume of the second cooling air depends on the ventilation speed of the fan 7. The semiconductor device of which the ventilation speed of the fan 7 is variable can variably control the cooling effect in the housing 6.

The semiconductor device may be provided with a temperature sensor (not shown) and a fan controller (not shown). The temperature sensor is provided in the housing 6 and measures the temperature of the semiconductor module 2 or inside the housing 6. The fan controller changes the rotation speed of the fan 7 in accordance with the result of the temperature measurement by the temperature sensor. With such a configuration, the semiconductor device increases the gas volume of the second cooling air to improve the cooling effect when the calorific value in the housing 6 is large, and decreases the rotational speed of the fan 7 when the calorific value in the housing is small; thereby reduction in power consumption is ensured.

The semiconductor module 2 is, for example, screwed to the one surface 4a of the base portion 4 of the heat sink 5 via heat radiation grease. Alternatively, for example, the semiconductor module 2 may be attached to the heat sink 5 via another heat radiation member such as a heat radiation sheet. Further, by polishing the one surface 4a of the base portion 4 on which the semiconductor module 2 is attached, the thermal resistance interposed between the semiconductor module 2 and the heat sink 5 can be reduced. Further, radiant heat radiated from the heat sink 5 can be reduced, and an effect of preventing a temperature rise of components in the housing 6 can be obtained.

The semiconductor module 2 is mounted on the circuit board 1 by, for example, soldering a plurality of terminals 2a protruding from the outer surface of the semiconductor module 2 to the circuit board 1. Alternatively, for example, the semiconductor module 2 may be mounted on the circuit board 1 by press-fit terminals. By mounting with the press-fit terminals, assemblability of the semiconductor device is improved.

The number of semiconductor modules 2 attached to the heat sink 5 is not fixed. However, when a plurality of semiconductor modules are attached to the heat sink 5, each semiconductor module is attached to the heat sink 5 via a heat radiation member having an insulating property.

The base portion 4 and the fins 3 of the heat sink 5 may be separate components or may be an integral component. If they are separate components, they are connected, for example, by calking or brazing. In the case of an integral component, both components are integrally molded by, for example, extrusion molding or aluminum die casting.

The cutout portion 4c of the heat sink 5 is formed by cutting a part of the base portion 4 before caulking or brazing. Alternatively, the cutout portion 4c may be formed by extrusion molding or aluminum die casting using a die having a shape corresponding to the cutout portion 4c.

### Embodiment 2

A semiconductor device according to Embodiment 2 will be described. Note that the description of the same configuration and operation as in Embodiment 1 is omitted.

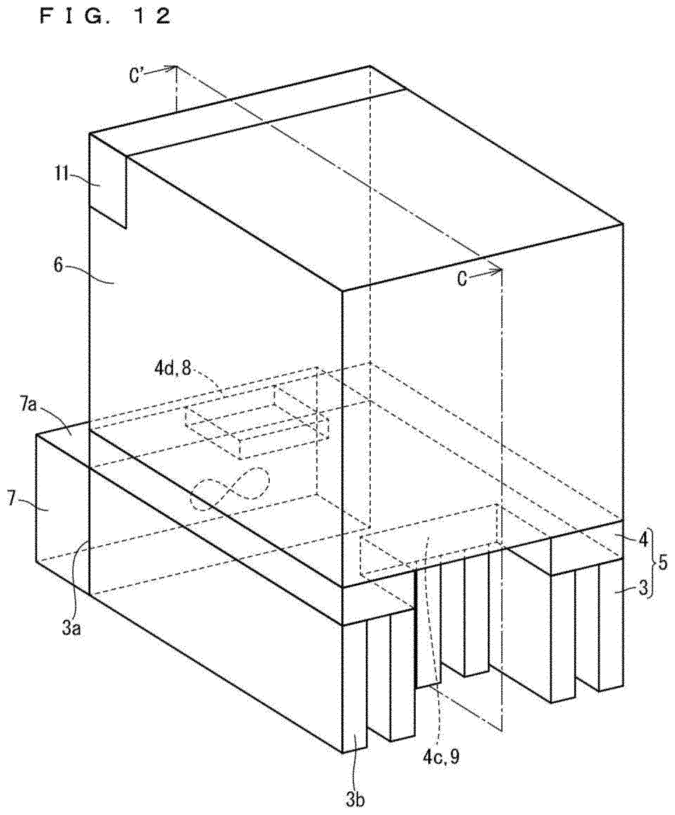

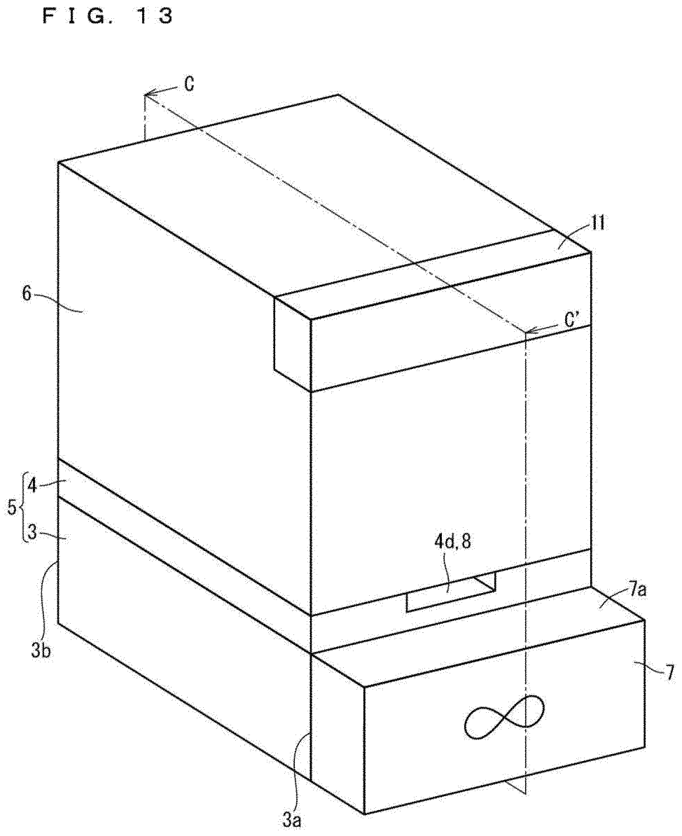

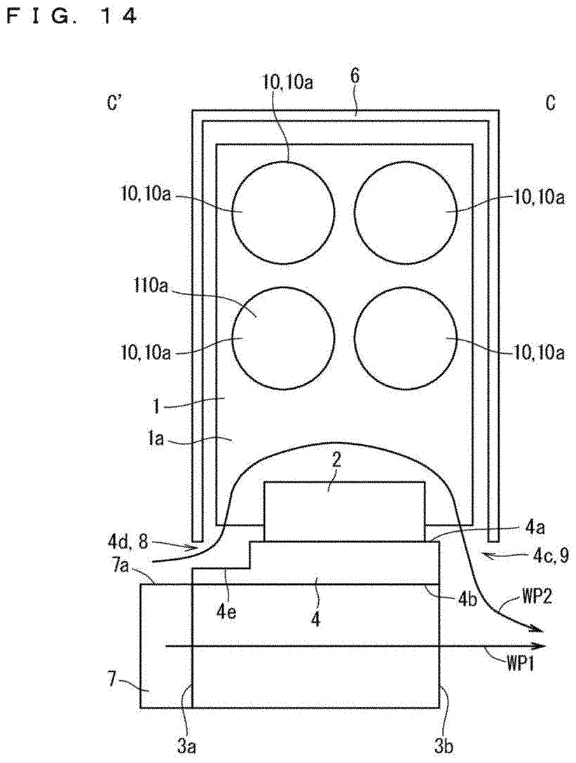

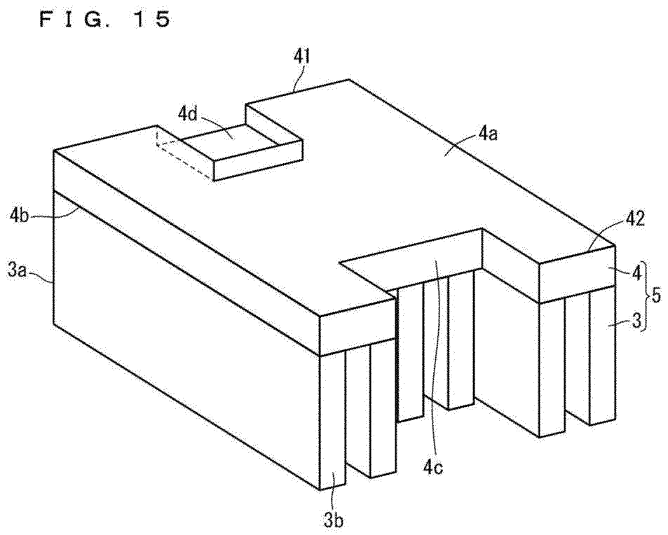

FIG. 12 and FIG. 13 are perspective views schematically illustrating a configuration of a semiconductor device according to Embodiment 2. FIG. 13 illustrates the semiconductor device as viewed from the opposite side to FIG. 12. FIG. 14 is a cross-sectional view schematically illustrating the configuration of the semiconductor device according to Embodiment 2, showing a cross section taken along line C-C′ illustrated in FIG. 12 and FIG. 13. FIG. 15 is a perspective view schematically illustrating a configuration of a heat sink 5 included in the semiconductor device according to Embodiment 2. As illustrated in FIG. 14, the circuit board 1 of Embodiment 2 is attached at a position rotated by 90 degrees with respect to the attaching position of the circuit board 1 of the semiconductor device according to Embodiment 1 illustrated in FIG. 2. In Embodiment 2, in the attaching direction of the semiconductor device, the back of the drawing in FIG. 14 is the lower side, and the front of the drawing is the upper side.

As illustrated in FIG. 15, the base portion 4 is provided with a step portion 4d and a cutout portion 4c. The step portion 4d is provided on one surface 4a including at least a part of the first side 41 forming the plate shape of the base portion 4. The first side 41 on which the step portion 4d is provided is located on the one end 3a side of the fins 3. That is, the step portion 4d is formed on the side where the fan 7 is attached. Further, the step portion 4d does not extend through the base portion 4.

The cutout portion 4c extends through the one surface 4a and the other surface 4b at least in a part of the second side 42 forming a plate shape. The second side 42 on which the cutout portion 4c is provided is located on the other end 3b side of the fins 3. That is, the configuration of cutout portion 4c is the same as that of the Embodiment 1.

As illustrated in FIG. 14, the fan 7 is provided on the one end 3a side of the fins 3 and sends the first cooling air by sending out the air from the one end 3a side toward the other end 3b side. However, the fan 7 is provided such that the upper end portion 7a is located below a surface defined by the bottom surface 4e of the step portion 4d. In Embodiment 2, the upper end portion 7a of the fan 7 is located at substantially the same height as the fins 3, and is located at a position lower than the bottom surface 4e of the step 4d. That is, the fan 7 is provided such that the upper end portion 7a is located at a position equal to or lower than the surface defined by the other surface 4b of the base portion 4. The lower side indicates a direction in which the fins 3 are located with respect to the base portion 4.

The first ventilation port 8 includes at least a part of the step portion 4d. In Embodiment 2, the first ventilation port 8 is formed by the step portion 4d. The first ventilation port 8 is provided above the half-height of the highest part (uppermost parts 110a) in height of the electronic components 10 from the surface 1a of the circuit board 1. In the semiconductor device illustrated in FIG. 14, the front side in the drawing is the upper side. For example, the first ventilation port 8 is provided such that the center of the first ventilation port 8 is located above the half-height.

The second ventilation port 9 includes at least a part of the cutout portion 4c. In Embodiment 2, the second ventilation port 9 is formed by the cutout portion 4c. For example, the second ventilation port 9 is also preferably provided above the half-height of the uppermost part 110a.

As described above, the configuration of the semiconductor device according to Embodiment 2 is substantially the same as that of Embodiment 1, however, Embodiment 2 is different from Embodiment 1 in that the first ventilation port 8 is not provided in the housing 6 but is provided in the step portion 4d of the heat sink 5.

In the semiconductor device according to Embodiment 2, the step portion 4d is located above the fan 7; therefore, a portion of the first cooling air does not flow into the housing 6 through the step portion 4d. Accordingly, outside air, that is, the second cooling air is taken in from the outside of the housing 6 through the step portion 4d, and is discharged through the cutout portion 4c. And, the second wind path WP2 in which the second cooling air flows is formed between the step portion 4d that is the first ventilation port 8 and the cutout portion 4c that is the second ventilation port 9.

(Effects)

With such a configuration, the semiconductor device can improve the cooling effect of the components mounted close to the second wind path WP2 for the second cooling air. The semiconductor module 2 is air-cooled by the second cooling air in addition to the cooling by the heat sink 5. Therefore, the cooling performance of the semiconductor module 2 is improved without improving the performance of the fan 7. As a result, the semiconductor device can prevent the characteristic change due to the temperature change of the semiconductor module 2 and can improve the reliability of the semiconductor device per se. Further, the semiconductor device improves the cooling effect of not only the semiconductor module 2 but also other electronic components 10 such as the capacitor 10a mounted close to the second wind path WP2 for the second cooling air. As a result, the lives of the electronic components 10 are extended, and moreover, the reliability of the semiconductor device is improved.

In the semiconductor device of Embodiment 1, in order to form the second wind path WP2 in the housing 6, both the housing 6 and the heat sink 5 need to be processed. However, in the semiconductor device of Embodiment 2, the second wind path WP2 can be formed only by processing the heat sink 5. The semiconductor device can be manufactured at a low cost with a suppressed increase in the number of processing steps.

The configuration of the first ventilation port 8 is not limited to the above configuration. When the first ventilation port 8 is formed only with the step portion 4d, the first ventilation port 8 cannot have an opening larger than the thickness of the base portion 4. However, a hole may be further provided on the housing 6 as another first ventilation port near the step portion 4d in the housing 6. Thereby, in the semiconductor device, the inlet of the second cooling air larger than the thickness of the base portion 4 can be secured as the first ventilation port, and the cooling effect is improved. Further, by providing another first ventilation port at a location different from the step portion 4d, a plurality of second wind paths are also formed.

Also, the shapes of the cutout portion 4c and the step portion 4d are not fixed. For example, the shape of the step portion 4d may have a slope corresponding to the direction in which air flows. Thereby, the cooling effect is improved without interruption of the air flow.

(Modification of Embodiment 2)

As in the same with Modification 4 of Embodiment 1, the fan 7 may be provided on the cutout portion 4c side, that is, the other end 3b side of the fins 3 (now shown). The fan 7 included in the semiconductor device of Modification of Embodiment 2 sends the first cooling air toward the other end 3b side by taking in air from one end 3a side of the fins 3. Even with the semiconductor device having such a configuration, the same effects as those of the Embodiment 2 can be obtained.

In this case, the upper end portion 7a of the fan 7 is preferably provided at a position higher than the position of the cutout portion 4c. That is, the fan 7 is preferably provided such that the upper end portion 7a is provided above a surface defined by the other surface 4b of the base portion 4. The upper side indicates a direction in which the upper surface 6a of the housing 6 is located. With such a configuration, the fan 7 also takes in the second cooling air discharged from the second ventilation port 9 and discharges the air to the outside of the housing 6.

### Embodiment 3

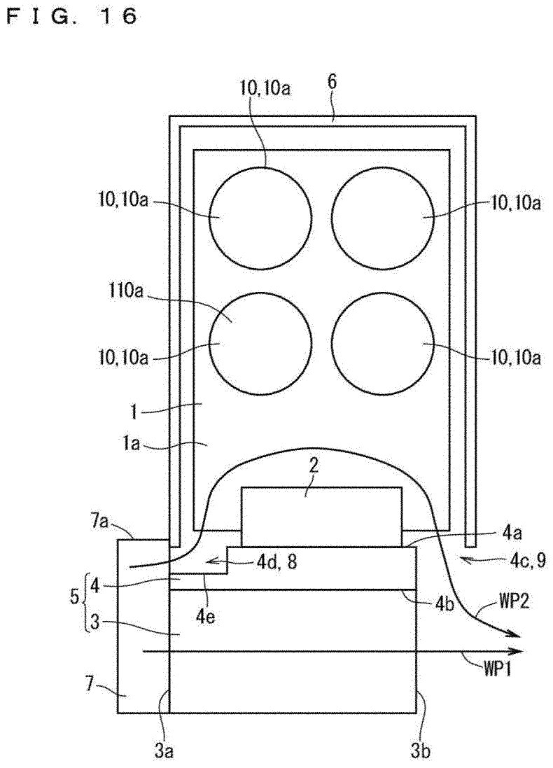

A semiconductor device according to Embodiment 3 will be described. FIG. 16 is a cross-sectional view schematically illustrating a configuration of a semiconductor device according to Embodiment 3. The semiconductor device according to Embodiment 3 differs from Embodiment 2 in the configuration of the fan 7. The description of the same configuration and operation as in Embodiment 2 is omitted. In Embodiment 3, in the attaching direction of the semiconductor device, the back of the drawing in FIG. 16 is the lower side, and the front of the drawing is the upper side.

The fan 7 not only sends the first cooling air to the first wind path WP1, but also sends the second cooling air toward the first ventilation port 8. In Embodiment 3, the fan 7 is provided on the one end 3a side of fins 3. And, the upper end portion 7a of the fan 7 is located at the position higher than the bottom surface 4e of the step 4d. That is, the fan 7 is provided such that the upper end portion 7a is located above a surface defined by the bottom surface 4e of the step portion 4d of the base portion 4.

In the semiconductor device according to Embodiment 2, the step portion 4d is located above the fan 7; therefore, a portion of the cooling air does not flow into the housing 6 through the step portion 4d. On the other hand, in the semiconductor device of Embodiment 3, the step portion 4d is located below the upper end portion 7a of the fan 7; therefore, the second cooling air sent by the fan 7 is taken into the housing 6 through the step portion 4d. The first ventilation port 8 and the second ventilation port 9 form the second wind path WP2 in which the second cooling air is taken in from the first ventilation port 8 and is discharged from the second ventilation port 9 by the fan 7 sending the second cooling air toward the first ventilation port 8.

(Effects)

With such a configuration, the semiconductor module 2 not only radiates heat to the surface in contact with the heat sink 5, but also forcibly receives the second cooling air from the surface opposite to the surface in contact with the heat sink 5 and is cooled. The semiconductor device can improve the cooling effect without improving the size of the heat sink 5 or the performance of the fins 3. The semiconductor device can prevent the characteristic change of the semiconductor module 2 due to the temperature change and can improve the reliability of the semiconductor device per se. In Embodiment 3, although the first ventilation port 8 is configured by the step portion 4d, and the second ventilation port 9 is configured by the cutout portion 4c, the configurations of the first ventilation port 8 and the second ventilation port 9 are not limited thereto. The first ventilation port 8 may have any configuration as long as the configuration allows the fan 7 to send the second cooling air to the first ventilation port 8, send the first cooling air toward the fins 3, and form the second wind path between the first ventilation port 8 and the second ventilation port 9.

Further, the first ventilation port 8 and the second ventilation port 9 in Embodiment 3 are formed only by processing the heat sink 5 as in the same with Embodiment 2. The semiconductor device can be manufactured at a low cost with a suppressed increase in the number of processing steps.

Adjustment of the depth of the step portion 4d, that is, the position of the bottom surface 4e or the position of the upper end portion 7a of the fan 7 allows the gas volume of the second cooling air flowing into the housing 6 to be adjusted. Therefore, the semiconductor device is adaptable in both the case where the effect of the natural air cooling in the housing 6 is to be enhanced and the case where the effect of the forced air cooling is to be enhanced.

In Embodiment 3, the step portion 4d may be configured to extend through the base portion 4. The inflow area of the cooling air sent from the fan 7 is expanded; therefore, the cooling effect in the housing 6 is improved.

Further, in the semiconductor device of Embodiment 3, the same configuration as that of Embodiment 2 exhibits the same effects as those of the Embodiment 2 above.

(Modification of Embodiment 3)

In Modification of Embodiment 3, the first ventilation port 8 is provided above the half-height of the highest part (uppermost parts 110a) in height of electronic components 10 from the surface 1a of the circuit board 1. In the semiconductor device illustrated in FIG. 16, the front side in the drawing is the upper side. For example, the first ventilation port 8 is provided such that the center of the first ventilation port 8 is located above the half-height.

For example, the second ventilation port 9 is also preferably provided above the half-height of the uppermost part 110a.

Such a semiconductor device can lower the wind speed of the second cooling air on the surface 1a of the circuit board 1 lower than the wind speed of the second cooling air on the electronic components 10. Therefore, the semiconductor device can discharge high-temperature air in the housing 6 while reducing the adhesion of foreign substances onto the surface 1a of the circuit board 1.

### Embodiment 4

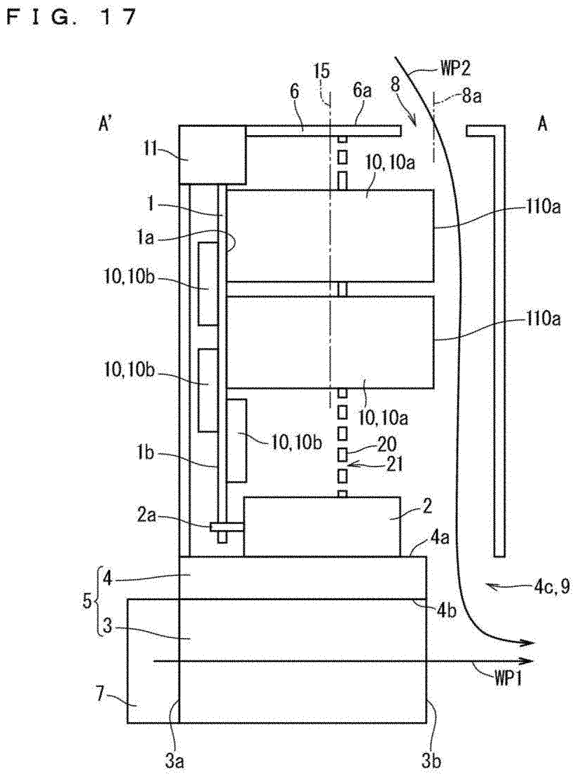

A semiconductor device according to Embodiment 4 will be described. FIG. 17 is a cross-sectional view schematically illustrating a configuration of a semiconductor device according to Embodiment 4. The semiconductor device according to Embodiment 4 is different from the semiconductor devices described in Embodiments 1 to 3 in that a plate 20 is provided between the second wind path WP2 and the circuit board 1 in housing 6. The description of the same configuration and operation as in Embodiments 1 to 3 is omitted.

Of the electronic components 10 mounted on the surface 1a of the circuit board 1, the height of the capacitor 10a from the circuit board 1 is the highest. The plate 20 is provided above the half-height 15 of the highest part (uppermost parts 110a) in height of the capacitor 10a from the surface 1a of the circuit board 1. The plate 20 is fixed to the housing 6 with screws, adhesive, welding, rivets, or the like.

The plate 20 has one or more openings 21. The openings 21 discharge the air heated by the heat generated during the operation of the circuit board 1 or the electronic components 10 toward the second wind path WP2. Then, the air discharged toward the second wind path WP2 is radiated to the outside of the semiconductor device by the second cooling air. Further, an opening 21 may be provided corresponding to the position of the electronic component 10 to facilitate the attachment of the plate 20. Such a plate 20 can be attached by inserting thereof with the position of the opening 21 being aligned with the electronic component 10 mounted on the circuit board 1.

(Effects)

In such a semiconductor device, the plate 20 prevents foreign matter such as dust and insects flowing into the housing 6 from the outside with the second cooling air from being deposited on the circuit board 1. Therefore, coating the circuit board 1 to prevent foreign matter from adhering is to be eliminated. Further, an installation of a filter or a labyrinth structure at the first ventilation port 8 is unnecessary. As a result, reduction in size and cost of the semiconductor device is ensured.

Further, contacting or fixing the electronic component 10 to the plate 20 prevents the electronic component 10 from being damaged by vibration generated during transportation or operation. In addition, heat is transmitted from the electronic component 10 to the plate 20; therefore, the performance of radiating heat generated in the electronic component 10 to the outside air is improved. As a result, improvement in reliability of the electronic component 10 and replacement of the electronic component 10 with an inexpensive component are ensured.

The material of the plate 20 is, for example, a resin such as acrylonitrile butadiene styrene (ABS), polybutylene terephthalate (PBT), and polyphenylene sulfide (PPS). Alternatively, for example, the material of the plate 20 is metal such as iron or aluminum. However, the material of the plate 20 is not limited thereto. In particular, when the plate 20 is made of metal, the plate 20 reduces electric noise. Further, the plate 20 may be a mesh-like member or a filter. The plate 20 does not need to be provided to cover the entire second wind path WP2.

Adjustment of the position of the opening 21 of the plate 20 allows control of the flow and the wind speed of the air in the housing 6.

Further, in the semiconductor device of Embodiment 4, the same configuration as that of Embodiments 1 to 3 exhibits the same effects as those of the Embodiments 1 to 3 above.

It should be noted that Embodiments of the present invention can be arbitrarily combined and can be appropriately modified or omitted without departing from the scope of the invention. While the invention has been described in detail, the forgoing description is in all aspects illustrative and not restrictive. It is understood that numerous other modifications and variations can be devised without departing from the scope of the invention.

### EXPLANATION OF REFERENCE SIGNS

1 circuit board, 2 semiconductor module, 3 fin, 3a one end, 3b other end, base portion, 41 first side, 42 second side, 4a one surface, 4b other surface, 4c cutout portion, 4d step portion, 4e bottom surface, 5 heat sink, 6 housing, 7 fan, 7a upper end portion, 8 first ventilation port, 9 second ventilation port, 10 electronic component, 12 electronic component heat sink, WP1 first wind path, WP2 second wind path.

1. A semiconductor device comprising:
a heat sink including fins forming a first wind path in which first cooling air flows from a first end toward a second end and a base portion having a plate shape, the heat sink being provided with a semiconductor module on a first surface of the base portion and the fins standing on a second surface of the base portion;
a housing attached to the base portion of the heat sink and covering the first surface of the base portion, the semiconductor module, an electronic component operating in association with the semiconductor module, and a circuit board to which the electronic component is mounted, the housing accommodating the semiconductor module in a space formed between the first surface and the housing;
a fan configured to send the first cooling air toward the first wind path to cool the fins;
a first ventilation port communicating inside of the housing and outside of the housing and configured to take second cooling air into the housing; and
a second ventilation port communicating inside of the housing and outside of the housing and configured to discharge the second cooling air taken into the housing to the outside of the housing, wherein
the first ventilation port is provided above a half-height of a highest part in height of the electronic component from the circuit board, the electronic component being mounted on a surface of the circuit board in the housing,
the second ventilation port extends through the first surface and the second surface of the base portion in the housing, and
the semiconductor device further comprises, in the housing, a second wind path in which the second cooling air is taken in from the first ventilation port and discharged from the second ventilation port to the outside of the housing due to a pressure difference between inside of the housing and outside of the housing formed at the second ventilation port due to a flow of the first cooling air.

2-13. (canceled)

14. The semiconductor device according to claim 1, wherein
a wind speed of the second cooling air on the surface of the circuit board is lower than a wind speed of the second cooling air on the electronic component.

15. The semiconductor device according to claim 1, wherein
the second ventilation port is provided above the half-height of the highest part of the electronic component.

16. The semiconductor device according to claim 1, wherein
the first ventilation port is provided on the housing,
the base portion has a cutout portion extending through the first surface and the second surface at least in a part of one side forming the plate shape,
the one side on which the cutout portion is provided locates on the second end side of the fins, and
the second ventilation port includes at least a part of the cutout portion.

17. The semiconductor device according to claim 1, wherein
the base portion has a step portion provided on the first surface and including at least a part of a first side forming the plate shape and a cutout portion extending through the first surface and the second surface at least in a part of a second side forming the plate shape,
the first side on which the step portion is provided locates on the first end side of the fins,
the second side on which the cutout portion is provided locates on the second end side of the fins,
the first ventilation port includes at least a part of the step portion, and
the second ventilation port includes at least a part of the cutout portion.

18. The semiconductor device according to claim 1, wherein
the fan is provided on the first end side of the fins and configured to send the first cooling air by sending out air from the first end side toward the second end side.

19. The semiconductor device according to claim 18, wherein
the fan is provided such that an upper end portion of the fan is located lower than a surface defined by the second surface of the base portion.

20. The semiconductor device according to claim 1, wherein
the fan is provided on the second end side of the fins and configured to send the first cooling air by drawing in air from the first end side toward the second end side.

21. The semiconductor device according to claim 1, further comprising
an electronic component heat sink provided in the second wind path formed in the housing and configured to cool the electronic component.

22. A semiconductor device comprising:
a heat sink including fins forming a first wind path in which first cooling air flows from a first end toward a second end and a base portion having a plate shape, the heat sink being provided with a semiconductor module on a first surface of the base portion and the fins standing on a second surface of the base portion;
a housing attached to the base portion of the heat sink and covering the first surface of the base portion, the semiconductor module, an electronic component operating in association with the semiconductor module, and a circuit board to which the component is mounted, the housing accommodating the semiconductor module in a space formed between the first surface and the housing;
a fan configured to send the first cooling air toward the first wind path to cool the fins;
a first ventilation port communicating inside of the housing and outside of the housing and configured to take second cooling air into the housing; and
a second ventilation port communicating inside of the housing and outside of the housing and configured to discharge the second cooling air taken into the housing to the outside of the housing, wherein
the fan is configured to send the second cooling air toward the first ventilation port further, and
the fan sends the second cooling air toward the first ventilation port, thereby the first ventilation port and the second ventilation port forming, in the housing, a second wind path in which the second cooling air is taken in from the first ventilation port and discharged from the second ventilation port to the outside of the housing.

23. The semiconductor device according to claim 22, wherein
the first ventilation port is provided above a half-height of a highest part in height of the electronic component from the circuit board, the electronic component being mounted on a surface of the circuit board in the housing, and
a wind speed of the second cooling air on the surface of the circuit board is lower than a wind speed of the second cooling air on the electronic component.

24. The semiconductor device according to claim 23, wherein
the second ventilation port is provided above the half-height of the highest part of the electronic component.

25. The semiconductor device according to claim 22, wherein
the base portion has a step portion provided on the first surface and including at least a part of a first side forming the plate shape and a cutout portion extending through the first surface and the second surface at least in a part of a second side forming the plate shape,
the first side on which the step portion is provided locates on the first end side of the fins,
the second side on which the cutout portion is provided locates on the second end side of the fins,
the first ventilation port includes at least a part of the step portion, and
the second ventilation port includes at least a part of the cutout portion, and
the fan is provided on the first end side of the fins and provided such that an upper end portion of the fan is located above a surface defined by a bottom surface of the step portion of the base portion.

26. The semiconductor device according to claim 22, further comprising
an electronic component heat sink provided in the second wind path formed in the housing and configured to cool the electronic component.
